(19) United States
(12) Patent Application Publication
(10) Pub. No.: US 2022/0052035 A1
(43) Pub. Date: Feb. 17, 2022

(54) VERTICAL ELECTROSTATIC DISCHARGE PROTECTION DEVICE

(71) Applicant: AMAZING MICROELECTRONIC CORP., NEW TAIPEI CITY (TW)

(72) Inventors: CHING-WEN WANG, HSINCHU COUNTY (TW); CHIH-WEI CHEN, TAOYUAN CITY (TW); MEI-LIAN FAN, HSINCHU COUNTY (TW); KUN-HSIEN LIN, HSINCHU CITY (TW)

(21) Appl. No.: 16/993,523

(22) Filed: Aug. 14, 2020

(51) Int. Cl. H01L 27/02; H01L 27/06

(52) U.S. Cl. CPC H01L 27/0248; H01L 27/0664

(57) ABSTRACT

A vertical electrostatic discharge protection device includes a heavily-doped semiconductor substrate, a first semiconductor epitaxial layer, a first doped buried layer, a second semiconductor epitaxial layer, a first doped well, at least one second doped well, and a first heavily-doped area. The epitaxial layers are stacked on the substrate. The first doped buried layer is formed in the first semiconductor epitaxial layer. The first doped well is formed in the second semiconductor epitaxial layer. The first doped well is formed on the first doped buried layer, and the doping concentration of the first doped well is lower than that of the first doped buried layer. The second doped well is formed in the second semiconductor epitaxial layer. The second doped well is adjacent to the first doped well.

### BACKGROUND OF THE INVENTION

### Field of the Invention

The present invention relates to the vertical electrostatic discharge (ESD) technology, particularly to a vertical electrostatic discharge protection device.

### Description of the Related Art

Electrostatic Discharge (ESD) damage has become the main reliability issue for CMOS IC products fabricated in the nanoscale CMOS processes. ESD protection device is generally designed to bypass the ESD energy, so that the IC chips can be prevented from ESD damages.

The working principle of ESD protection device is shown in FIG. 1. In FIG. 1, the ESD protection device 8 is connected in parallel with a protected circuit 9 on the IC chip. The ESD protection device 8 would be triggered immediately when the ESD event occurs. In that way, the ESD protection device 8 can provide a superiorly low resistance path for discharging the transient ESD current, so that the energy of the ESD transient current can be bypassed by the ESD protection device 8. For the purpose of reducing the size and surface areas occupied by the ESD protection device 8, a vertical transient voltage suppressor is implemented instead of a horizontal transient voltage suppressor. However, the conventional vertical transient voltage suppressor has some drawbacks. For example, in the U.S. Pat. No. 7,781,826, the substrate and the epitaxial layer belong to the same conductivity type. Besides, the P-type well is used as the base of the BJT. The breakdown interface is formed between the P-type well and the epitaxial layer. The breakdown voltage of the interface is difficultly controlled since the depth of the P-type well depends on the width of the base. In the U.S. Pat. No. 8,288,839, the vertical transient voltage suppressor is implemented with a bipolar junction transistor, wherein the base of the bipolar junction transistor is floating. Thus, the bipolar junction transistor is a bidirectional device, not a unidirectional device. In the U.S. Pat. No. 9,666,700, electrodes are formed on the surface of the vertical bipolar junction transistor. Thus, the electrodes occupy many footprint areas.

To overcome the abovementioned problems, the present invention provides a vertical electrostatic discharge protection device, so as to solve the afore-mentioned problems of the prior art.

### SUMMARY OF THE INVENTION

The present invention provides a vertical electrostatic discharge protection device, which independently adjusts a gain and a breakdown voltage.

In an embodiment of the present invention, a vertical electrostatic discharge protection device is provided. The vertical electrostatic discharge protection device includes a heavily-doped semiconductor substrate, a first semiconductor epitaxial layer, a first doped buried layer, a second semiconductor epitaxial layer, a first doped well, at least one second doped well, and a first heavily-doped area. The heavily-doped semiconductor substrate has a first conductivity type. The first semiconductor epitaxial layer has the first conductivity type. The first semiconductor epitaxial layer is formed on the heavily-doped semiconductor substrate. The first doped buried layer has a second conductivity type. The first doped buried layer is formed in the first semiconductor epitaxial layer. The first doped buried layer emerges and implants from the top of the first semiconductor epitaxial layer. The second semiconductor epitaxial layer has the first conductivity type. The second semiconductor epitaxial layer is formed on the first semiconductor epitaxial layer and the first doped buried layer. The first doped well has the second conductivity type. The first doped well is formed in the second semiconductor epitaxial layer. The first doped well is also formed on the first doped buried layer. Further, the doping concentration of the first doped well may be substantially lower than the doping concentration of the first doped buried layer. The second doped well has the second conductivity type. The second doped well is formed in the second semiconductor epitaxial layer, wherein the second doped well is adjacent to the first doped well or directly touches the first doped well. The first heavily-doped area has the first conductivity type. The first heavily-doped area is formed in the first doped well, wherein the first heavily-doped area is coupled to the second doped well through an external conductor. The thickness of the first doped well between the first heavily-doped area and the first doped buried layer may be substantially higher than the thickness of the first doped buried layer.

In an embodiment of the present invention, the first conductivity type is an N type and the second conductivity type is a P type.

In an embodiment of the present invention, the first conductivity type is a P type and the second conductivity type is an N type.

In an embodiment of the present invention, the at least one second doped well comprises a plurality of second doped wells.

In an embodiment of the present invention, the at least one second doped well surrounds the first doped well.

In an embodiment of the present invention, the first heavily-doped area extends to the second doped well.

In an embodiment of the present invention, the at least one second doped well directly touches the first doped well.

In an embodiment of the present invention, the doping concentration of the second doped well is substantially higher than the doping concentration of the first doped well.

In an embodiment of the present invention, the vertical electrostatic discharge protection device further includes at least one second heavily-doped area, the second heavily-doped area has the second conductivity type, and the second heavily-doped area is formed in the second doped well.

In an embodiment of the present invention, the vertical electrostatic discharge protection device further includes at least one second doped buried layer, the second doped buried layer has the second conductivity type, the second doped buried layer is formed in the first semiconductor epitaxial layer, the second doped buried layer emerges and implants from the top of the first semiconductor epitaxial layer.

In an embodiment of the present invention, the second doped buried layer directly touches the bottom of the second doped well.

In an embodiment of the present invention, the heavily-doped semiconductor substrate is coupled to a first pin, and the second doped well and the first heavily-doped area are coupled to a second pin through the external conductor.

In an embodiment of the present invention, the heavily-doped semiconductor substrate is coupled to a first pin, and the second heavily-doped area and the first heavily-doped area are coupled to a second pin through the external conductor.

To sum up, the vertical electrostatic discharge protection device includes a bipolar junction transistor and a diode, wherein the base and the emitter of the bipolar junction transistor are coupled to each other to enhance the ESD capability. The vertical electrostatic discharge protection device forms a first doped well and a doped buried layer in two epitaxial layers, respectively. The first doped well and the doped buried layer are respectively used to dominate the breakdown voltage and the gain of the bipolar junction transistor, such that the breakdown voltage and the gain are independently controlled. In addition, since the high doping concentration of the second doped well further reduce the forward voltage of the diode, the ESD capability of the diode is also enhanced.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating an ESD protection device connected with a protected circuit on an IC chip in the conventional technology;

FIG. 2 is a cross-sectional view of a vertical electrostatic discharge protection device according to a first embodiment of the present invention;

FIG. 3 is a schematic diagram illustrating an equivalent circuit of a vertical electrostatic discharge protection device according to an embodiment of the present invention;

FIG. 4 is a cross-sectional view of a vertical electrostatic discharge protection device according to a second embodiment of the present invention;

FIG. 5 is a cross-sectional view of a vertical electrostatic discharge protection device according to a third embodiment of the present invention;

FIG. 6 is a cross-sectional view of a vertical electrostatic discharge protection device according to a fourth embodiment of the present invention;

FIG. 7 is a schematic diagram illustrating an equivalent circuit of a vertical electrostatic discharge protection device according to another embodiment of the present invention;

FIG. 8 is a cross-sectional view of a vertical electrostatic discharge protection device according to a fifth embodiment of the present invention; and

FIG. 9 is a cross-sectional view of a vertical electrostatic discharge protection device according to a sixth embodiment of the present invention.

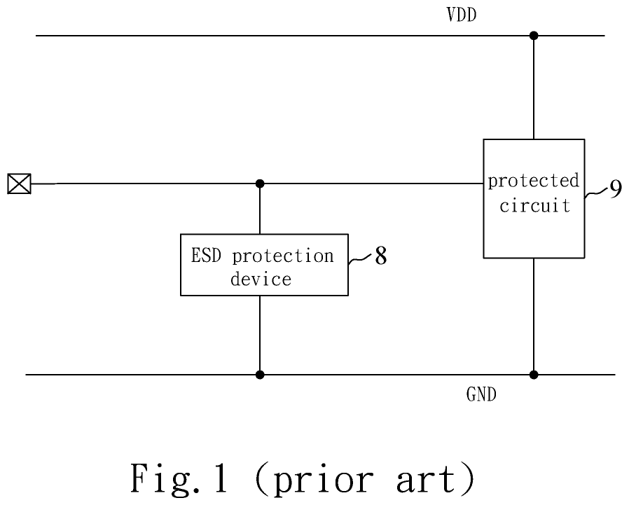

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express that the embodiment in the present invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

For the purpose of reducing the surface areas occupied by the ESD protection device, enhancing the ESD level without increasing the areas occupied by the ESD protection device, and achieving uniform current distribution and good heat dissipation, a vertical electrostatic discharge protection device is provided.

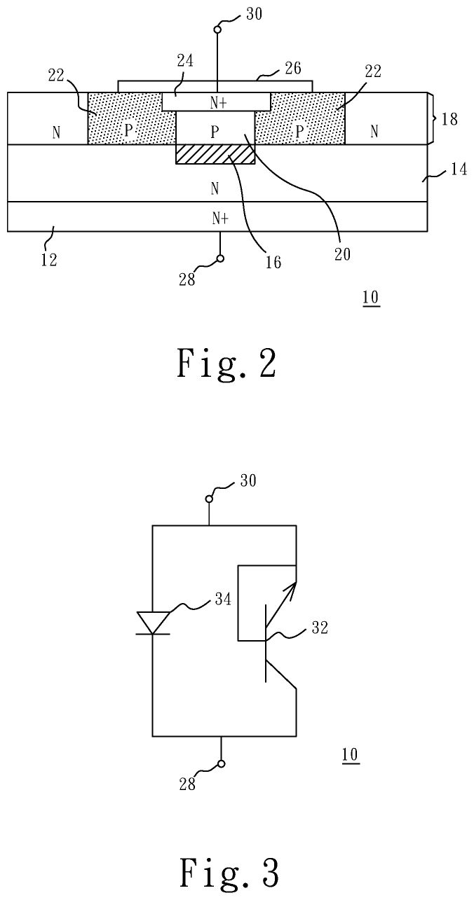

FIG. 2 is a cross-sectional view of a vertical electrostatic discharge protection device according to a first embodiment of the present invention. Referring to FIG. 2, the first embodiment of the vertical electrostatic discharge protection device 10 includes a heavily-doped semiconductor substrate 12, a first semiconductor epitaxial layer 14, a first doped buried layer 16, a second semiconductor epitaxial layer 18, a first doped well 20, at least one second doped well 22, and a first heavily-doped area 24. The heavily-doped semiconductor substrate 12, the first semiconductor epitaxial layer 14, the second semiconductor epitaxial layer 18, and the first heavily-doped area 24 have a first conductivity type. The first doped well 20, the second doped well 22, and the first doped buried layer 16 have a second conductivity type. In the first embodiment, the first conductivity type is an N type and the second conductivity type is a P type. The first heavily-doped area 24 may have a shape of a cuboid, but the present invention is not limited thereto. In the first embodiment, one or more second doped wells 22 can be used. The first embodiment exemplifies one second doped well 22 for clarity and convenience.

The first semiconductor epitaxial layer 14 is formed on the heavily-doped semiconductor substrate 12. The first doped buried layer 16 is formed in the first semiconductor epitaxial layer 14. The first doped buried layer 16 emerges and implants from the top of the first semiconductor epitaxial layer 14. The second semiconductor epitaxial layer 18 is formed on the first semiconductor epitaxial layer 14 and the first doped buried layer 16. The first doped well 20 is formed in the second semiconductor epitaxial layer 18 and formed on the first doped buried layer 16. In some embodiment of the present invention, the bottom of the first doped well 20 directly touches the first doped buried layer 16. In other words, there is nothing between the first doped well 20 and the first doped buried layer 16. In addition, the doping concentration of the first doped well 20 may be substantially lower than the doping concentration of the first doped buried layer 16. Thus, the first doped buried layer 16 may be a heavily-doped buried layer. The second doped well 22 is formed in the second semiconductor epitaxial layer 18 and is adjacent to the first doped well 20. In some embodiment of the present invention, the second doped well 22 directly touches the first doped well 20. That is to say, there is nothing between the second doped well 22 and the first doped well 20. The second doped well 22 may surround the first doped well 20. In some embodiment of the present invention, the doping concentration of the second doped well 22 may be substantially higher than the doping concentration of the first doped well 20. The first heavily-doped area 24 is formed in the first doped well 20. In some embodiments of the present invention, the first heavily-doped area 24 may extend to the second doped well 22. The first heavily-doped area 24 is coupled to the second doped well 22 through an external conductor 26, such as a conductive trace or a conduction layer. The thickness of the first doped well 20 between the first heavily-doped area 24 and the first doped buried layer 16 may be substantially higher than the thickness of the first doped buried layer 16. For example, the thickness of the first doped well 20 between the first heavily-doped area 24 and the first doped buried layer 16 is at least 3 μm, but the present invention is not limited thereto.

The position of the first doped buried layer 16 is greatly deeper than that of the first doped well 20 since the first semiconductor epitaxial layer 14 and the second semiconductor epitaxial layer 18 are formed. The heavily-doped semiconductor substrate 12 is coupled to a first pin 28, and the second doped well 22 and the first heavily-doped area 24 are coupled to a second pin 30 through the external conductor 26.

FIG. 3 is a schematic diagram illustrating an equivalent circuit of a vertical electrostatic discharge protection device according to an embodiment of the present invention. Referring to FIG. 2 and FIG. 3, the heavily-doped semiconductor substrate 12, the first semiconductor epitaxial layer 14, the first doped buried layer 16, the first doped well 20, and the first heavily-doped area 24 form a bipolar junction transistor 32. The heavily-doped semiconductor substrate 12 and the first semiconductor epitaxial layer 14 form the collector of the bipolar junction transistor 32. The first doped buried layer 16 and the first doped well 20 form the base of the bipolar junction transistor 32. The first heavily-doped area 24 is used as the emitter of the bipolar junction transistor 32. The heavily-doped semiconductor substrate 12, the first semiconductor epitaxial layer 14, and the second doped well 22 form a diode 34. The heavily-doped semiconductor substrate 12 and the first semiconductor epitaxial layer 14 form the cathode of the diode 34. The second doped well 22 is used as the anode of the diode 34. If there is a plurality of second doped wells 22, a plurality of diodes 34 will be formed.

When positive ESD energy is applied to the first pin 28 and the second pin 30 is grounded, the ESD current flows from the first pin 28 to the second pin 30 through the heavily-doped semiconductor substrate 12, the first semiconductor epitaxial layer 14, the first doped buried layer 16, the first doped well 20, and the first heavily-doped area 24, and the avalanche breakdown event occurs at an interface between the first semiconductor epitaxial layer 14 and the first doped buried layer 16. Thus, the breakdown voltage of the interface between the first semiconductor epitaxial layer 14 and the first doped buried layer 16 is dominated by the first doped buried layer 16. Since the thickness of the first doped well 20 between the first heavily-doped area 24 and the first doped buried layer 16 is substantially higher than the thickness of the first doped buried layer 16, the gain of the bipolar junction transistor 32 is also dominated by the first doped well 20. Accordingly, the breakdown voltage and the gain are independently controlled. Besides, since the doping concentration of the second doped well 22 may be substantially higher than the doping concentration of the first doped well 20, the ESD current is suppressed to flow from the first pin 28 to the second pin 30 through the heavily-doped semiconductor substrate 12, the first semiconductor epitaxial layer 14, the second doped well 22, the first heavily-doped area 24, and the external conductor 26. Simultaneously, the current crowding effect at the corner of the first heavily-doped area 24 formed in the second doped well 22 is avoided. This is because the gain of the bipolar junction transistor 32 is higher than that of the bipolar junction transistor formed by the heavily-doped semiconductor substrate 12, first semiconductor epitaxial layer 14, the second doped well 22, and the first heavily-doped area 24.

When positive ESD energy is applied to the second pin 30 and the first pin 28 is grounded, the ESD current flows from the second pin 30 to the first pin 28 through the external conductor 26, the second doped well 22, the first semiconductor epitaxial layer 14, and the heavily-doped semiconductor substrate 12. The higher the doping concentration of the second doped well 22, the lower the forward voltage of the diode 34, and the higher the ESD capability of the diode 34.

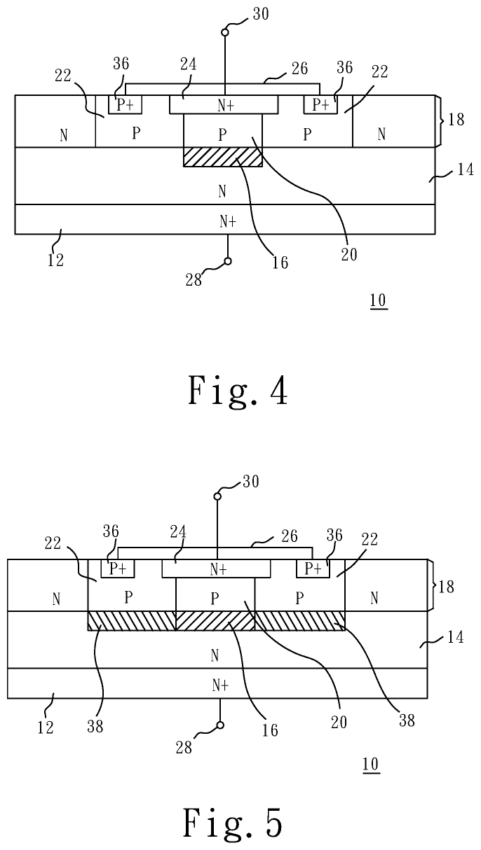

FIG. 4 is a cross-sectional view of a vertical electrostatic discharge protection device according to a second embodiment of the present invention. Referring to FIG. 4, the second embodiment of the vertical electrostatic discharge protection device 10 is introduced as follows. Compared with the first embodiment, the second embodiment further includes at least one second heavily-doped area 36. The second heavily-doped area 36 has the second conductivity type. The second heavily-doped area 36 is formed in the second doped well 22. The second doped well 22 is coupled to the external conductor 36 through the second heavily-doped area 36. The second heavily-doped area 36 is used to reduce the resistance between the second doped well 22 and the external conductor 26. For convenience and clarity, the second embodiment exemplifies one second heavily-doped area 36 that surrounds the first heavily-doped area 24. If there is a plurality of second doped wells 22, a plurality of second heavily-doped areas 36 is respectively formed in the plurality of second doped wells 22.

Referring to FIG. 3 and FIG. 4, the heavily-doped semiconductor substrate 12, the first semiconductor epitaxial layer 14, the second doped well 22, and the second heavily-doped area 36 form the diode 34. The heavily-doped semiconductor substrate 12 and the first semiconductor epitaxial layer 14 form the cathode of the diode 34. The second doped well 22 and the second heavily-doped area 36 form the anode of the diode 34.

When positive ESD energy is applied to the second pin 30 and the first pin 28 is grounded, the ESD current flows from the second pin 30 to the first pin 28 through the external conductor 26, the second heavily-doped area 36, the second doped well 22, the first semiconductor epitaxial layer 14, and the heavily-doped semiconductor substrate 12. The higher the doping concentration of the second doped well 22, the lower the forward voltage of the diode 34, and the higher the ESD capability of the diode 34.

FIG. 5 is a cross-sectional view of a vertical electrostatic discharge protection device according to a third embodiment of the present invention. Referring to FIG. 5, the third embodiment of the vertical electrostatic discharge protection device 10 is introduced as follows. Compared with the second embodiment, the third embodiment further includes at least one second doped buried layer 38. The second doped buried layer 38 has the second conductivity type. The second doped buried layer 38 is formed in the first semiconductor epitaxial layer 14. The second doped buried layer 38 emerges and implants from the top of the first semiconductor epitaxial layer 14. In some embodiment of the present invention, the second doped buried layer 38 directly touches the bottom of the second doped well 22. The doping concentration of the second doped well 22 is substantially lower than the doping concentration of the second doped buried layer 38. Thus, the second doped buried layer 38 may be a heavily-doped buried layer. For convenience and clarity, the third embodiment exemplifies one second doped buried layer 38 that surrounds the first doped buried layer 16. If there is a plurality of second doped wells 22, a plurality of second doped buried layers 38 is formed in the first semiconductor epitaxial layer 14. The second doped buried layers 38 emerge and implant from the top of the first semiconductor epitaxial layer 14 and directly respectively touch the bottom of the second doped wells 22.

Referring to FIG. 3 and FIG. 5, the heavily-doped semiconductor substrate 12, the first semiconductor epitaxial layer 14, the second doped well 22, the second doped buried layer 38, and the second heavily-doped area 36 form the diode 34. The heavily-doped semiconductor substrate 12 and the first semiconductor epitaxial layer 14 form the cathode of the diode 34. The second doped well 22, the second doped buried layer 38, and the second heavily-doped area 36 form the anode of the diode 34.

When positive ESD energy is applied to the first pin 28 and the second pin 30 is grounded, the ESD current flows from the first pin 28 to the second pin 30 through the heavily-doped semiconductor substrate 12, the first semiconductor epitaxial layer 14, the first doped buried layer 16, the first doped well 20, and the first heavily-doped area 24. Due to the second doped buried layer 38, the ESD current is further suppressed to flow from the first pin 28 to the second pin 30 through the heavily-doped semiconductor substrate 12, the first semiconductor epitaxial layer 14, the second doped buried layer 38, the second doped well 22, the first heavily-doped area 24, and the external conductor 26. Simultaneously, the current crowding effect at the corner of the first heavily-doped area 24 formed in the second doped well 22 is further avoided.

When positive ESD energy is applied to the second pin 30 and the first pin 28 is grounded, the ESD current flows from the second pin 30 to the first pin 28 through the external conductor 26, the second heavily-doped area 36, the second doped well 22, the second doped buried layer 38, the first semiconductor epitaxial layer 14, and the heavily-doped semiconductor substrate 12. The higher the doping concentration of the second doped well 22 and the second doped buried layer 38, the lower the forward voltage of the diode 34, and the higher the ESD capability of the diode 34.

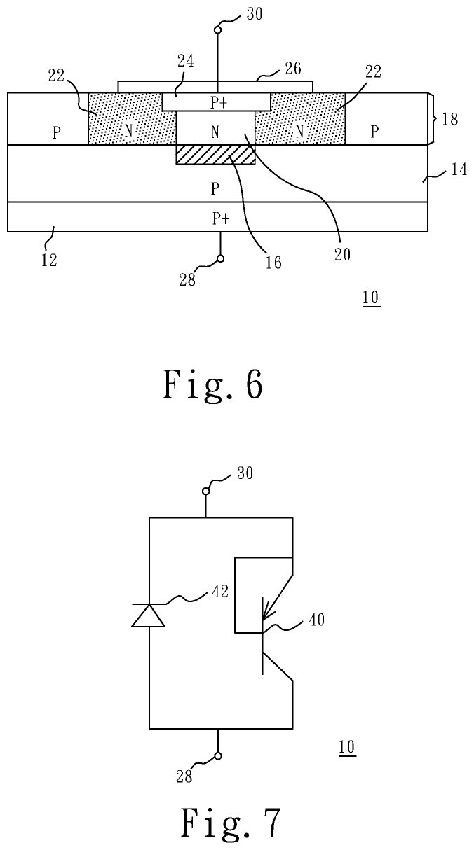

FIG. 6 is a cross-sectional view of a vertical electrostatic discharge protection device according to a fourth embodiment of the present invention. The fourth embodiment is different from the first embodiment in the conductivity types. The first conductivity type and the second conductivity type of the fourth embodiment are respectively a P type and an N type. The other structures of the seventh embodiment have been described in the first embodiment so will not be reiterated.

FIG. 7 is a schematic diagram illustrating an equivalent circuit of a vertical electrostatic discharge protection device according to another embodiment of the present invention. Referring to FIG. 6 and FIG. 7, the heavily-doped semiconductor substrate 12, the first semiconductor epitaxial layer 14, the first doped buried layer 16, the first doped well 20, and the first heavily-doped area 24 form a bipolar junction transistor 40. The heavily-doped semiconductor substrate 12 and the first semiconductor epitaxial layer 14 form the collector of the bipolar junction transistor 40. The first doped buried layer 16 and the first doped well 20 form the base of the bipolar junction transistor 40. The first heavily-doped area 24 is used as the emitter of the bipolar junction transistor 40 and used to reduce the resistance between the base and the second pin 30. As a result, the first heavily-doped area 24 as the emitter is coupled to the first doped well 20 as the base through the second doped well 22 and the external conductor 26, such that the ESD capability is improved. The heavily-doped semiconductor substrate 12, the first semiconductor epitaxial layer 14, and the second doped well 22 form a diode 42. The heavily-doped semiconductor substrate 12 and the first semiconductor epitaxial layer 14 form the anode of the diode 42. The second doped well 22 is used as the cathode of the diode 42. If there is a plurality of second doped wells 22, a plurality of diodes 42 will be formed.

When positive ESD energy is applied to the second pin 30 and the first pin 28 is grounded, the ESD current flows from the second pin 30 to the first pin 28 through the first heavily-doped area 24, the first doped well 20, the first doped buried layer 16, the first semiconductor epitaxial layer 14, and the heavily-doped semiconductor substrate 12, and the avalanche breakdown event occurs at an interface between the first semiconductor epitaxial layer 14 and the first doped buried layer 16. Thus, the breakdown voltage of the interface between the first semiconductor epitaxial layer 14 and the first doped buried layer 16 is dominated by the first doped buried layer 16. Since the thickness of the first doped well 20 between the first heavily-doped area 24 and the first doped buried layer 16 is substantially higher than the thickness of the first doped buried layer 16, the gain of the bipolar junction transistor 32 is dominated by the first doped well 20. Accordingly, the breakdown voltage and the gain are independently controlled. Besides, since the doping concentration of the second doped well 22 may be substantially higher than the doping concentration of the first doped well 20, the ESD current is suppressed to flow from the second pin 30 to the first pin 28 through the external conductor 26, the first heavily-doped area 24, the second doped well 22, the first semiconductor epitaxial layer 14, and the heavily-doped semiconductor substrate 12. Simultaneously, the current crowding effect at the corner of the first heavily-doped area 24 formed in the second doped well 22 is avoided. This is because the gain of the bipolar junction transistor 40 is higher than that of the bipolar junction transistor formed by the first semiconductor epitaxial layer 14, the second doped well 22, and the first heavily-doped area 24.

When positive ESD energy is applied to the first pin 28 and the second pin 30 is grounded, the ESD current flows from the first pin 28 to the second pin 30 through the heavily-doped semiconductor substrate 12, the first semiconductor epitaxial layer 14, the second doped well 22, and the external conductor 26. The higher the doping concentration of the second doped well 22, the lower the forward voltage of the diode 40, and the higher the ESD capability of the diode 40.

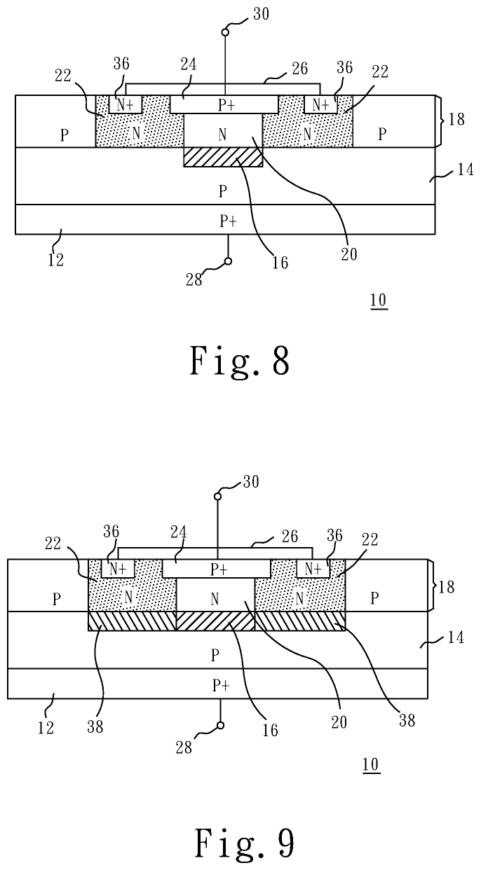

FIG. 8 is a cross-sectional view of a vertical electrostatic discharge protection device according to a fifth embodiment of the present invention. Referring to FIG. 8, the fifth embodiment of the vertical electrostatic discharge protection device 10 is introduced as follows. Compared with the fourth embodiment, the fifth embodiment further includes at least one second heavily-doped area 36. The second heavily-doped area 36 has the second conductivity type. The second heavily-doped area 36 is formed in the second doped well 22. The second doped well 22 is coupled to the external conductor 26 through the second heavily-doped area 36. The second heavily-doped area 36 is coupled to the second pin 30 through the external conductor 26. The second heavily-doped area 36 is used to reduce the resistance between the second doped well 22 and the external conductor 26. For convenience and clarity, the fifth embodiment exemplifies one second heavily-doped area 36 that surrounds the first heavily-doped area 24. If there is a plurality of second doped wells 22, a plurality of second heavily-doped areas 36 is respectively formed in the plurality of second doped wells 22.

Referring to FIG. 7 and FIG. 8, the heavily-doped semiconductor substrate 12, the first semiconductor epitaxial layer 14, the second doped well 22, and the second heavily-doped area 36 form the diode 34. The heavily-doped semiconductor substrate 12 and the first semiconductor epitaxial layer 14 form the anode of the diode 42. The second doped well 22 and the second heavily-doped area 36 form the cathode of the diode 42.

When positive ESD energy is applied to the first pin 28 and the second pin 30 is grounded, the ESD current flows from the first pin 28 to the second pin 30 through the heavily-doped semiconductor substrate 12, the first semiconductor epitaxial layer 14, the second doped well 22, the second heavily-doped area 36, and the external conductor 26. The higher the doping concentration of the second doped well 22, the lower the forward voltage of the diode 42, and the higher the ESD capability of the diode 42.

FIG. 9 is a cross-sectional view of a vertical electrostatic discharge protection device according to a sixth embodiment of the present invention. Referring to FIG. 9, the sixth embodiment of the vertical electrostatic discharge protection device 10 is introduced as follows. Compared with the fifth embodiment, the sixth embodiment further includes at least one second doped buried layer 38. The second doped buried layer 38 has the second conductivity type. The second doped buried layer 38 is formed in the first semiconductor epitaxial layer 14. The second doped buried layer 38 emerges and implants from the top of the first semiconductor epitaxial layer 14. In some embodiment of the present invention, the second doped buried layer 38 directly touches the bottom of the second doped well 22. The doping concentration of the second doped well 22 is substantially lower than the doping concentration of the second doped buried layer 38. Thus, the second doped buried layer 38 may be a heavily-doped buried layer. For convenience and clarity, the sixth embodiment exemplifies one second doped buried layer 38 that surrounds the first doped buried layer 16. If there is a plurality of second doped wells 22, a plurality of second doped buried layers 38 is formed in the first semiconductor epitaxial layer 14. The second doped buried layers 38 emerge and implant from the top of the first semiconductor epitaxial layer 14 and directly respectively touch the bottom of the second doped wells 22.

Referring to FIG. 7 and FIG. 9, the heavily-doped semiconductor substrate 12, the first semiconductor epitaxial layer 14, the second doped well 22, the second doped buried layer 38, and the second heavily-doped area 36 form the diode 42. The heavily-doped semiconductor substrate 12 and the first semiconductor epitaxial layer 14 form the anode of the diode 42. The second doped well 22, the second doped buried layer 38, and the second heavily-doped area 36 form the cathode of the diode 42.

When positive ESD energy is applied to the second pin 30 and the first pin 28 is grounded, the ESD current flows from the second pin 30 to the first pin 28 through the first heavily-doped area 24, the first doped well 20, the first doped buried layer 16, the first semiconductor epitaxial layer 14, and the heavily-doped semiconductor substrate 12. Due to the second doped buried layer 38, the ESD current is further suppressed to flow from the second pin 30 to the first pin 28through the external conductor 26, the first heavily-doped area 24, the second doped well 22, the second doped buried layer 38, the first semiconductor epitaxial layer 14, and the heavily-doped semiconductor substrate 12. Simultaneously, the current crowding effect at the corner of the first heavily-doped area 24 formed in the second doped well 22 is further avoided.

When positive ESD energy is applied to the first pin 28 and the second pin 30 is grounded, the ESD current flows from the first pin 28 to the second pin 30 through the heavily-doped semiconductor substrate 12, the first semiconductor epitaxial layer 14, the second doped buried layer 38, the second doped well 22, the second heavily-doped area 36, and the external conductor 26. The higher the doping concentration of the second doped well 22 and the second doped buried layer 38, the lower the forward voltage of the diode 42, and the higher the ESD capability of the diode 42.

According to the embodiments provided above, the vertical electrostatic discharge protection device can include a bipolar junction transistor and a diode, wherein the base and the emitter of the bipolar junction transistor are coupled to each other to enhance the ESD capability. In addition, the vertical electrostatic discharge protection device forms a doped well and a doped buried layer in two epitaxial layers, respectively. The doped well and the doped buried layer are respectively used to dominate the breakdown voltage and the gain of the bipolar junction transistor, such that the breakdown voltage and the gain are independently controlled.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A vertical electrostatic discharge protection device comprising:
a heavily-doped semiconductor substrate having a first conductivity type;
a first semiconductor epitaxial layer, having the first conductivity type, formed on the heavily-doped semiconductor substrate;
a first doped buried layer, having a second conductivity type, formed in the first semiconductor epitaxial layer, wherein the first doped buried layer emerges and implants from a top of the first semiconductor epitaxial layer;
a second semiconductor epitaxial layer, having the first conductivity type, formed on the first semiconductor epitaxial layer and the first doped buried layer;
a first doped well, having the second conductivity type, formed in the second semiconductor epitaxial layer, and the first doped well is formed on the first doped buried layer;
at least one second doped well, having the second conductivity type, formed in the second semiconductor epitaxial layer, wherein the at least one second doped well is adjacent to the first doped well; and
a first heavily-doped area, having the first conductivity type, formed in the first doped well, wherein the first heavily-doped area is coupled to the at least one second doped well through an external conductor.

2. The vertical electrostatic discharge protection device according to claim 1, wherein the first conductivity type is an N type and the second conductivity type is a P type.

3. The vertical electrostatic discharge protection device according to claim 1, wherein the first conductivity type is a P type and the second conductivity type is an N type.

4. The vertical electrostatic discharge protection device according to claim 1, wherein doping concentration of the first doped well is substantially lower than doping concentration of the first doped buried layer.

5. The vertical electrostatic discharge protection device according to claim 1, wherein a bottom of the first doped well directly touches the first doped buried layer.

6. The vertical electrostatic discharge protection device according to claim 1, wherein the at least one second doped well comprises a plurality of second doped wells.

7. The vertical electrostatic discharge protection device according to claim 1, wherein the at least one second doped well surrounds the first doped well.

8. The vertical electrostatic discharge protection device according to claim 1, wherein the at least one second doped well directly touches the first doped well.

9. The vertical electrostatic discharge protection device according to claim 1, wherein doping concentration of the at least one second doped well is substantially higher than doping concentration of the first doped well.

10. The vertical electrostatic discharge protection device according to claim 1, wherein the first heavily-doped area extends to the at least one second doped well.

11. The vertical electrostatic discharge protection device according to claim 1, further comprising at least one second heavily-doped area, the at least one second heavily-doped area has the second conductivity type, and the at least one second heavily-doped area is formed in the at least one second doped well.

12. The vertical electrostatic discharge protection device according to claim 1, further comprising at least one second doped buried layer, the at least one second doped buried layer has the second conductivity type, the at least one second doped buried layer is formed in the first semiconductor epitaxial layer, the at least one second doped buried layer emerges and implants from a top of the first semiconductor epitaxial layer.

13. The vertical electrostatic discharge protection device according to claim 12, wherein the at least one second doped buried layer directly touches a bottom of the at least one second doped well.

14. The vertical electrostatic discharge protection device according to claim 1, wherein the heavily-doped semiconductor substrate is coupled to a first pin, and the at least one second doped well and the first heavily-doped area are coupled to a second pin through the external conductor.

15. The vertical electrostatic discharge protection device according to claim 11, wherein the heavily-doped semiconductor substrate is coupled to a first pin, and the at least one second heavily-doped area and the first heavily-doped area are coupled to a second pin through the external conductor.
